(19) United States
(12) Patent Application Publication
(10) Pub. No.: US 2025/0140589 A1
(43) Pub. Date: May 1, 2025

(54) PHOTOVOLTAIC ROBOT

(71) Applicant: SUZHOU JUNION INTELLIGENT TECHNOLOGY CO., LTD., Suzhou (CN)

(72) Inventors: Linxiao FU, Suzhou (CN); Lvchun Wang, Suzhou (CN); Guo Li, Suzhou (CN); Jinfei Geng, Suzhou (CN); Guiya Li, Suzhou (CN)

(21) Appl. No.: 18/653,581

(22) Filed: May 2, 2024

(30) Foreign Application Priority Data
Oct. 30, 2023 (CN) 202311420504.4
Oct. 30, 2023 (CN) 202322918745.3
Oct. 30, 2023 (CN) 202322918746.8

(51) Int. Cl. H01L 21/677; B60G 3/00; B60P 3/00

(52) U.S. Cl. CPC H01L 21/6773; B60G 3/00; B60P 3/00; H01L 21/67706; H01L 21/67724; H01L 21/67736

(57) ABSTRACT

The invention provides a photovoltaic robot including: a robot body, including a storage device and a walking mechanism disposed at the bottom of the storage device, where openings are provided on two sides of the storage device, and an interior space of the storage device is defined as a storage space; a conveying device, horizontally disposed in the storage space, where two ends of the conveying device extend out of the storage space from the openings on the storage device; and an overhaul window, hinged to the storage device at an opening on a side of the storage device, where the overhaul window is recessed from inside to outside to form an avoidance space. The conveying device extends out of the two sides of the storage device, and the avoidance space of the overhaul window is provided, which facilitates interior repair and cleaning of the storage device.

This application claims priority to Chinese Patent Application Nos. CN 202322918746.8, filed on Oct. 30, 2023, CN 202322918745.3, filed on Oct. 30, 2023, and CN 202311420504.4, filed on Oct. 30, 2023, all of which are incorporated by reference for all purposes as if fully set forth herein.

### FIELD OF THE INVENTION

The present invention relates to the field of photovoltaic production technologies, and in particular, to a photovoltaic robot.

### DESCRIPTION OF THE RELATED ART

A vehicle referred to as a “flower basket” needs to be used in a process of processing a silicon wafer. A silicon wafer is placed in a flower basket, and is circulated and transferred by a photovoltaic robot between different process devices. The photovoltaic robot usually includes a movement chassis and a storage bin body disposed on the movement chassis. A conveying device is disposed in the storage bin body. Generally, the movement chassis moves to process equipment, and conveyance equipment is docked with the process equipment to implement loading and unloading of the flower basket.

The silicon wafer is thin and brittle and is highly prone to breakage. Therefore, during the transport of the flower basket and a traveling process of the robot, it is highly likely to cause breakage to the silicon wafer, and as a result shattered pieces of the silicon wafer fall in the conveying device and the storage bin body. Moreover, during long-term running, floating dust is deposited on the storage bin body and the conveying device, which affects the cleanliness of the silicon wafer. Therefore, the photovoltaic robot needs to be cleaned.

In addition, one end of the conveying device of the photovoltaic robot needs to be docked with the process equipment. Therefore, a drive mechanism of the conveying device is usually disposed at the end away from the docked end, that is, is disposed in the storage bin body. The conveying device requires regular or irregular overhauls during long-term running.

In summary, there are requirements of repair and cleaning for the photovoltaic robot. The storage bin body has a particular depth in a conveyance direction of the conveying device, and it is rather inconvenient for an operator to directly perform interior repair and cleaning from the docked end. Therefore, in the prior art, to repair and clean the photovoltaic robot, a back plate of the photovoltaic robot usually needs to be removed before the storage bin body and the conveying device can be repaired and cleaned, and the back plate is mounted after the repair and cleaning are finished. In this manner, a disassembly and assembly process is complex, which greatly affects the efficiency of repair and cleaning.

### SUMMARY OF THE INVENTION

To overcome the deficiencies in the prior art, the present invention provides a photovoltaic robot.

The technical solution provided in the present inventions is as follows:

A photovoltaic robot, including:
a robot body, including a storage device and a walking mechanism disposed at a bottom of the storage device, where openings are provided on two sides of the storage device, and an interior space of the storage device is defined as a storage space;
a conveying device, horizontally disposed in the storage space of the storage device, where two ends of the conveying device extend out of the storage space from the openings on the two sides of the storage device; and
an overhaul window, hinged to the storage device at an opening on a side of the storage device, where the overhaul window is recessed from inside to outside to form an avoidance space.

In an embodiment of the present invention, the photovoltaic robot further includes a first locker unit disposed at an opening of the storage device and a second locker unit disposed at a side edge of the overhaul window, where the first locker unit and the second locker unit fit to each other and are used for locking the overhaul window after being closed.

In an embodiment of the present invention, the first locker unit includes a first locker support fixed at an opening of the storage device and a locker pin disposed on the first locker support;
the second locker unit includes a second locker support fixedly mounted at the side edge of the overhaul window, a locker body fixed on the second locker support, and a first rotating member and a second rotating member that are rotatably connected to the locker body and are rotatably resettable; a first lock slot is transversely opened on a side of the locker body close to the first locker unit; the first rotating member includes a lock tongue portion close to an end of the second rotating member and a force-applying portion away from the end of the second rotating member; a second lock slot and a locking slot are separately opened on a side edge of the second rotating member; and the second locker unit is configured to include a first state and a second state;
when the second locker unit is close to the first locker unit, the locker pin abuts against a slot edge of the second lock slot and pushes the second rotating member to rotate until the lock tongue portion of the first rotating member is locked in the locking slot, in this case, the locker pin is locked in a locking space formed through overlapping and surrounding of the first lock slot and the second lock slot, and the second locker unit is in the first state; and
when an external force is applied to the force-applying portion of the first rotating member to enable the lock tongue portion to be separated from the locking slot, the second rotating member is reset and rotates, the locking space is opened, the locker pin is pushed away from the locking space, and the second locker unit is in the second state.

In an embodiment of the present invention, the second locker unit further includes a first rotary member and a second rotary member that are vertically mounted on the locker body, a first torsion spring sleeved on the first rotary member, and a second torsion spring sleeved on the second rotary member; two end portions of the first torsion spring are respectively connected with the locker body and the first rotating member; and two end portions of the second torsion spring are respectively connected with the locker body and the second rotating member.

In an embodiment of the present invention, a side of the locker body is bent to form a first blocking portion used for being connected with the first torsion spring and a second blocking portion used for being connected with the second torsion spring, and the second blocking portion is further configured to limit the second rotating member after being rotated and reset.

In an embodiment of the present invention, a slot edge of the first lock slot close to the first rotating member obliquely extends from a slot opening of the first lock slot toward the second rotating member, to form a preset angle a between the slot edge of the first lock slot close to the first rotating member and a movement plane direction of the second locker unit.

In an embodiment of the present invention, a vertical direction of an extension direction of a side edge of the lock tongue portion away from the first rotary member points to a rotation center of the first rotating member.

In an embodiment of the present invention, the first locker support includes a first fixed portion and a first support portion, and the first fixed portion is fixedly connected to the storage device; and the locker pin is detachably mounted on the first support portion;
the second locker support includes a second fixed portion fixedly connected to an inner wall of the overhaul window and a mounting portion fixedly connected to the second fixed portion; the locker body is fixedly mounted on a side of the mounting portion close to the second fixed portion; a first avoidance slot used for avoiding the locker pin is transversely opened on a side edge of the mounting portion opposite to the first locker support; and a second avoidance slot used for avoiding the force-applying portion is opened in the second fixed portion; and
a through hole is opened on the side edge of the overhaul window for performing an operation on the force-applying portion.

In an embodiment of the present invention, the photovoltaic robot further includes an air purification device disposed at a top of the storage device.

In an embodiment of the present invention, the photovoltaic robot further includes a roller shutter device disposed at an opening on a side of the storage device away from the overhaul window.

In an embodiment of the present invention, the conveying device includes a main frame and a conveyance assembly mounted on the main frame, the main frame includes a middle support unit and two side support units that are disposed opposite to each other, and the middle support unit is disposed between the two side support units; and
the photovoltaic robot further includes a height adjustment assembly, the height adjustment assembly includes a fixed plate, a first bolt, and a second bolt, the fixed plate is disposed on the storage device, and the first bolt and the second bolt are threadedly connected to the fixed plate or the middle support unit, and are used for adjusting and fixing a distance between the middle support unit and the fixed plate.

In an embodiment of the present invention, the conveyance assembly includes an electric roller disposed on one end of the side support unit, a synchronous pulley disposed on the other end of the side support unit, and a synchronous belt transmission-connected to the electric roller and the synchronous pulley; and peripheral teeth that fit the synchronous belt by a transmission way are disposed on a peripheral surface of the electric roller.

In an embodiment of the present invention, the first bolt extends through the fixed plate from bottom to top and abuts against a bottom surface of the middle support unit, and the first bolt is threadedly connected to the fixed plate; and the second bolt extends through the middle support unit from top to bottom and is threadedly connected to the fixed plate.

In an embodiment of the present invention, the first bolt extends through the fixed plate from bottom to top and is threadedly connected to the middle support unit; and the second bolt extends through the middle support unit from top to bottom and abuts against a top surface of the fixed plate, and the second bolt is threadedly connected to the middle support unit.

In an embodiment of the present invention, the conveyance assembly further includes a limiting guide assembly, the limiting guide assembly includes a rib, a guide strip, and a guide strip support member, the rib is fixed on two sides of the main frame by the guide strip support member, and the guide strip is fixed on an end portion of the rib.

In an embodiment of the present invention, the rib includes a rib support fixed on the guide strip support member and a rib strip that is disposed on an inner side of the rib support and is detachably connected to the rib support.

In an embodiment of the present invention, the storage device includes a body frame and a connecting frame disposed at a bottom of the body frame; the connecting frame includes at least one connecting support and at least one single-layer frame, one end of the connecting support is connected to the bottom of the body frame, and the other end of the connecting support is connected to an upper surface of the single-layer structure; the walking mechanism includes a plurality of drive wheels disposed in a middle of the connecting frame and a plurality of driven wheels disposed at a bottom of the connecting frame; the drive wheels has a power source and are used for driving the storage device to move; and the driven wheels are used for supporting the storage device.

In an embodiment of the present invention, the single-layer frame includes at least two main beams parallel to each other, a node is formed between every two main beams, and the connecting support is disposed at the node.

In an embodiment of the present invention, the walking mechanism further includes a suspension mechanism disposed in the middle of the connecting frame; the drive wheels are mounted on the suspension mechanism; the suspension mechanism includes a swing member and an elastic member; two ends of the swing member are rotatably connected to the connecting frame and the elastic member respectively; and an end portion of the elastic member away from the swing member is rotatably connected to the connecting frame.

In an embodiment of the present invention, the suspension mechanism further includes a third fixed base and a support base fixedly connected to the bottom of the connecting frame, and the swing member is hinged to the third fixed base; and the elastic member is hinged to the support base.

Compared with the prior art, the foregoing technical solution of the present invention has the following advantages:

In the photovoltaic robot of the present invention, the conveying device extends out of two sides of the storage device. When the photovoltaic robot needs to be repaired and cleaned, operations can be performed from two ends of the conveying device by opening the overhaul window, to reduce inconvenience caused by a deep interior space of the storage device.

Moreover, one end of the conveying device extends out of the storage device, making it convenient to dock process equipment to convey a flower basket. The present invention can reduce the complexity of repair and cleaning, thereby greatly improving the efficiency of repair and cleaning.

### BRIEF DESCRIPTION OF THE DRAWINGS

To make the content of the present invention clearer and more comprehensible, the present invention is further described in detail below according to specific embodiments of the present invention and the accompanying drawings.

FIG. 1 is a side view of a photovoltaic robot in the present invention;

FIG. 2 is a side view of a storage device in the present invention, wherein a housing at one side thereof is omitted;

FIG. 3 is a schematic structural diagram of an overhaul window in the present invention;

FIG. 4 is a schematic structural diagram of a first locker unit and a second locker unit in the present invention;

FIG. 5 is a schematic structural diagram of a first locker unit in the present invention;

FIG. 6 is a schematic structural diagram of a second locker support in the present invention;

FIG. 7 is a schematic structural diagram of a second locker unit (with a second locker support excluded) in the present invention;

FIG. 8 is a schematic structural diagram of a locker body, a first rotary member, a second rotary member, a first torsion spring, and a second torsion spring in the present invention;

FIG. 9 is a diagram of a position relationship between a second locker unit (with a second locker support excluded) and a locker pin when the second locker unit is in an unlocked state;

FIG. 10 is a diagram of a position relationship between a second locker unit (with a second locker support excluded) and a locker pin when the second locker unit is in a locked state;

FIG. 11 is a schematic structural diagram of a second locker unit (with a second locker support excluded) when the second locker unit is in a locked state in the present invention;

FIG. 12 is a schematic structural diagram of a photovoltaic robot in the present invention;

FIG. 13 is a front view of a photovoltaic robot in the present invention;

FIG. 14 is a schematic structural diagram of a conveying device in the present invention;

FIG. 15 is an exploded view of a conveying device in the present invention;

FIG. 16 is a schematic structural diagram of a limiting guide assembly in FIG. 15;

FIG. 17 is a schematic enlarged view of A in FIG. 16;

FIG. 18 is a schematic structural diagram of a frame of a photovoltaic robot in the present invention;

FIG. 19 is a schematic structural diagram of a drive wheel and a suspension mechanism in the present invention;

FIG. 20 is a front view of a drive wheel and a suspension mechanism in the present invention;

FIG. 21 is a side view of a drive wheel and a suspension mechanism in the present invention; and

FIG. 22 is a schematic structural diagram of Embodiment 4 or Embodiment 5 of a photovoltaic robot in the present invention.

Reference numerals: 100, storage device; 101, frame; 1011, vertical support; 1012, transverse support; 102, housing; 103, partition; 104, connecting frame; 200, conveying device; 201, side support unit; 202, middle support unit; 203, electric roller; 204, synchronous pulley; 205, synchronous belt; 206, first fixed base; 207, second fixed base; 208, rib; 2081, rib support; 2082, rib strip; 209, guide strip; 210, guide strip support member; 211, photoelectric detection member; 300, overhaul window; 301, connecting component; 302, avoidance space; 303, inner locked handle; 304, first through hole; 305, first observation window; 306, second observation window; 400, first locker unit; 401, first locker support; 4011, first fixed portion; 4012, first support portion; 402, locker pin; 500, second locker unit; 501, second locker support; 5011, second fixed portion; 5012, mounting portion; 5013, first avoidance slot; 5014, second avoidance slot; 502, locker body; 5021, first lock slot; 5022, first blocking portion; 5023, second blocking portion; 503, first rotating member; 5031, lock tongue portion; 5032, force-applying portion; 504, second rotating member; 5041, second lock slot; 5042, locking slot; 505, locking space; 506, first rotary member; 507, second rotary member; 508, first torsion spring; 509, second torsion spring; 600, walking mechanism; 601, drive wheel; 6011, driving wheel; 6012, drive motor; 602, driven wheel; 603, suspension mechanism; 6031, swing member; 6032, third fixed base; 6033, connecting member; 6034, elastic member; 6035, support base; 6036, mounting flange; 700, air purification device; 800, roller shutter device; 900, height adjustment assembly; 901, fixed plate; 902, first bolt; and 903, second bolt.

### DETAILED DESCRIPTION OF THE PREFERRED EMBODIMENTS

The present invention is further described below with reference to the accompanying drawings and specific embodiments, to enable a person skilled in the art to better understand and implement the present invention. However, the embodiments are not used to limit the present invention.

The foregoing and other technical content, features, and effects of the present invention will be clearly presented in the following detailed description of the embodiments with reference to the accompanying drawings. The terms of directions such as up, down, left, right, front or back mentioned in the following embodiments are only the directions with reference to the accompanying drawings. Accordingly, the directional terms used are for illustration purposes and are not intended to limit the present invention, and furthermore, reference numerals in the same accompanying drawing denote the same elements in all of the embodiments.

At present, a photovoltaic robot has requirements of repair and cleaning. However, a storage bin body has a particular depth in a conveyance direction of a conveying device, and it is rather inconvenient for an operator to directly perform interior repair and cleaning from a docked end. Therefore, in the prior art, to repair and clean a photovoltaic flower basket robot, a back plate of the photovoltaic flower basket robot usually needs to be removed before the storage bin body and the conveying device can be repaired and cleaned, and the back plate is mounted after the repair and cleaning are finished. In this manner, a disassembly and assembly process is complex, which greatly affects the efficiency of repair and cleaning.

### Embodiment 1

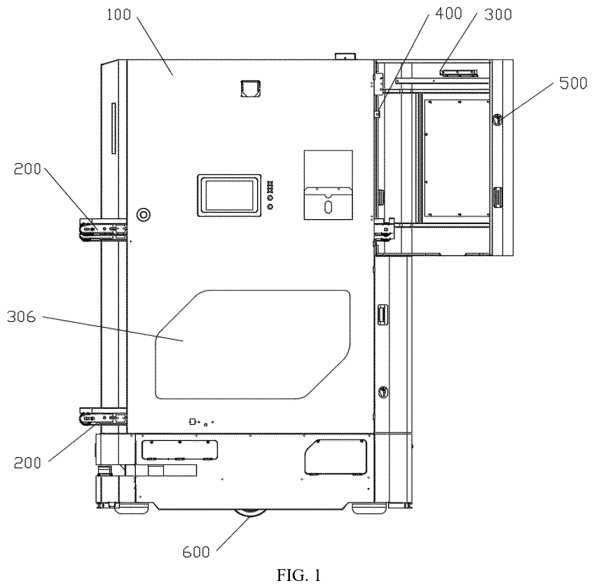

As shown in FIG. 1, to resolve the foregoing problem, this embodiment provides a photovoltaic robot.

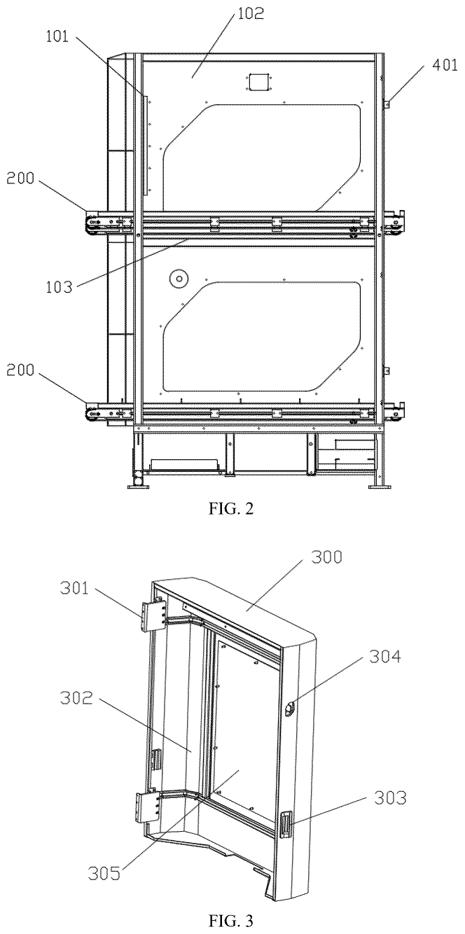

With reference to FIG. 1 to FIG. 3, the photovoltaic robot provided in this embodiment includes a robot body. The robot body includes a storage device 100 and a walking mechanism 600 disposed at a bottom of the storage device 100. The photovoltaic robot further includes a conveying device 200 disposed in the storage device 100 and an overhaul window 300 disposed on a side of the storage device 100 in a length direction of the conveying device 200.

The storage device 100 includes a frame 101, a housing 102 covering the frame 101, and a partition 103 disposed at the frame 101. The frame 101 and the housing 102 form a body frame. The housing 102 is disposed on two sides and a top of the frame 101 in a width direction of the conveying device 200, and is fixedly connected to the frame 101. In this way, the storage device 100 forms a cavity structure with openings in two sides. An interior space of the storage device 100 is defined as a storage space. The conveying device 200 is disposed in the storage space of the storage device 100. The storage space is in communication with the outside in the length direction of the conveying device 200. At least one second observation window 306 of a transparent material is disposed on the housing 102, to directly observe a running status of the conveying device 200 inside the storage device 100 or observe the cleanliness inside the storage device 100 through the second observation window 306.

In a further embodiment, the partition 103 is mounted on a support structure fixedly connected to the frame 101 or is directly fixedly connected to the frame 101. The interior space of the storage device 100 is separated into a plurality of independent storage spaces. In this embodiment, the partition 103 divides the interior space of the storage device 100 into two layers of independent storage spaces. In addition, two conveying devices 200 are disposed side by side in every independent storage space.

The conveying device 200 is horizontally disposed in the storage device 100 and is fixed on the frame 101. The length direction of the conveying device 200 is consistent with a length direction of the storage space. In addition, two ends of the conveying device 200 respectively extend out of the storage space of the storage device 100. In one aspect, a problem of docking the conveying device 200 with external equipment to convey a material is resolved. In another aspect, a length of the conveying device 200 in the storage device 100 is reduced, making it convenient to repair and clean the conveying device 200 and the storage device 100 from the two ends of the conveying device respectively. In this embodiment, the conveying device 200 transports a flower basket in a belt conveyance manner. The conveying device 200 of a belt conveyance structure may be equivalently replaced with another conveying device, for example, a table/roller conveying device. A specific structure of the conveying device 200 is not related to the technical problem to be resolved in this application. Details are not described herein again.

The walking mechanism 600 is mounted at the bottom of the frame 101, and is used for driving the storage device 100 to walk in any direction. The walking mechanism 600 include a drive wheel and a driven wheel. The drive wheel is provided with a power input. Specifically, the drive wheel may be a reduction-drive wheel connected with a motor, and the driven wheel may be a universal wheel.

The overhaul window 300 is hinged to the frame 101 by a connecting component 301, and an avoidance space 302 is provided on a side of the overhaul window 300 opposite to the storage space. Specifically, the overhaul window 300 is disposed at an opening of the storage device 100 away from an end docked with the external equipment. The connecting component 301 may be a hinge, and is hinged to the frame 101 of the storage device 100. The overhaul window 300 is recessed from inside to outside to form the avoidance space 302. When the overhaul window 300 is closed, the overhaul window 300 is recessed in a direction away from the conveying device 200. In one aspect, interference with the conveying device 200 during closing of the overhaul window 300 is avoided. In another aspect, a problem that the storage space is reduced because the conveying device 200 extends out of the storage device 100 is mitigated, to ensure a capacity of transporting flower baskets of the photovoltaic robot. An inner locked handle 303 is disposed at a side edge of the overhaul window 300 opposite to the connecting component 301, making it convenient to apply a force to open the overhaul window 300. Moreover, a mounting space of the photovoltaic robot is not occupied.

Further, at least one first observation window 305 of a transparent material is disposed in the overhaul window 300, so that an interior status of the storage device 100 can be observed from a different viewing angle in addition to the second observation window 306 in the housing 102.

When the photovoltaic robot needs to be repaired and cleaned, operations can be performed from the two ends of the conveying device 200 by opening the overhaul window 300, to reduce inconvenience caused by a deep interior space of the storage device 100. Moreover, one end of the conveying device 200 extends out of the storage device 100, to facilitate docking with process equipment to convey a flower basket. After the overhaul window 300 is opened, the other end of the conveying device 200 extends out of the storage device 100, it can be convenient to repair and clean the conveying device 200. The foregoing solution can reduce the complexity of repair and cleaning, thereby greatly improving the efficiency of repair and cleaning.

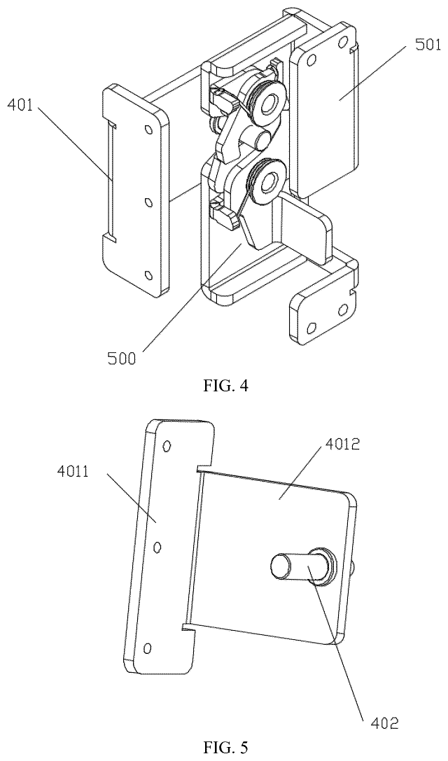

As shown in FIG. 4, in a further embodiment, the photovoltaic robot further includes a first locker unit 400 and a second locker unit 500. The first locker unit 400 is disposed at an opening of the storage device 100, and the second locker unit 500 is disposed at the side edge of the overhaul window 300. The first locker unit 400 fits the second locker unit 500. The first locker unit 400 and the second locker unit 500 lock the closed overhaul window 300, to keep the overhaul window 300 from being opened without cause. In one aspect, the deposition of floating dust is reduced. In another aspect, the safety during transportation or cushioning of a flower basket is improved.

In this embodiment, the first locker unit 400 includes a first locker support 401 fixedly mounted at a side edge of the frame 101 and a locker pin 402 disposed at the first locker support 401.

For a structure of the first locker support 401, refer to FIG. 5. The first locker support 401 includes a first fixed portion 4011 and a first support portion 4012 that are disposed. The first fixed portion 4011 and the first support portion 4012 are bent opposite, and the first fixed portion 4011 is fixedly connected to the storage device 100. The locker pin 402 is detachably mounted on the first support portion 4012. Specifically, the locker pin 402 is disposed at the first support portion 4012, and threads are disposed at an end of the locker pin 402. A threaded hole (not shown) is correspondingly opened in the first support portion 4012. The locker pin 402 is threadedly connected to the first support portion 4012, to implement a connection between the locker pin 402 and the first locker support 401. If the fit between the first locker unit 400 and the second locker unit 500 is insecure due to damage and deformation of the locker pin 402, the locker pin 402 can be conveniently and quickly replaced.

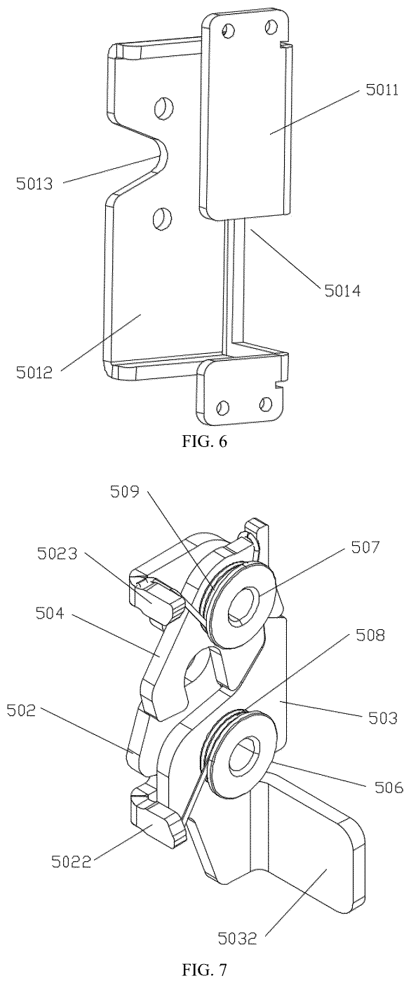

With reference to FIG. 6 to FIG. 8, the second locker unit 500 includes a second locker support 501 fixedly mounted at the side edge of the overhaul window 300, a locker body 502 fixed on the second locker support 501, and a first rotating member 503 and a second rotating member 504 that are rotatably connected to the locker body 502 and are rotatably resettable.

For a structure of the second locker support 501, refer to FIG. 6, the second locker support 501 includes a second fixed portion 5011 and a mounting portion 5012. The second fixed portion 5011 is fixedly connected to an inner wall of the overhaul window 300. The mounting portion 5012 is fixedly connected to the second fixed portion 5011. The locker body 502 is fixedly mounted on a side of the mounting portion 5012 close to the second fixed portion 5011. A space is reserved between the second fixed portion 5011 and the mounting portion 5012, to mount the locker body 502, the first rotating member 503, the second rotating member 504, and the like.

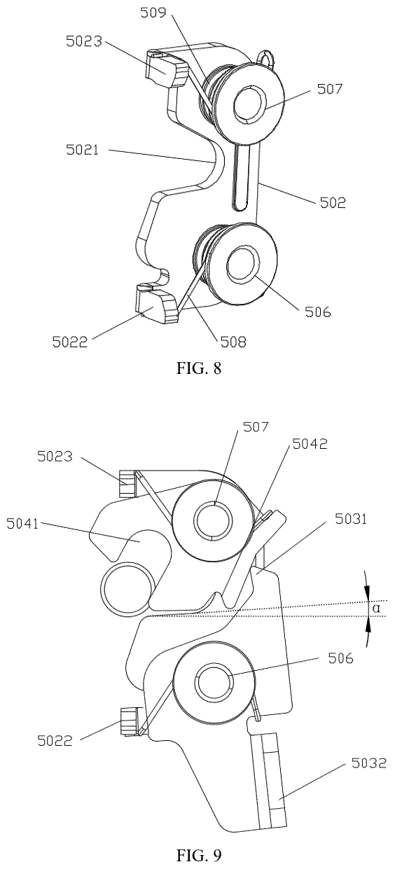

For structures of the locker body 502, the first rotating member 503, and the second rotating member 504, refer to FIG. 7 and FIG. 8. The first rotating member 503 and the second rotating member 504 are rotatably connected to the locker body 502. In addition, the first rotating member 503 and the second rotating member 504 are rotatably resettable. The locker body 502 is fixedly mounted at the mounting portion 5012 of the second locker support 501, and specifically, is mounted on a side surface of the mounting portion 5012 facing the second fixed portion 5011. A bottom corner on a side of the locker body 502 is bent to form a first blocking portion 5022, and a top corner of the locker body 502 on the same side is bent to form a second blocking portion 5023. A first lock slot 5021 is transversely opened on a side of the locker body 502 close to the first locker unit 400. Bending angles of the first blocking portion 5022 and the second blocking portion 5023 may be the same or different, and the bending angles are designed according to mounting requirements.

In this embodiment, the second locker unit 500 further includes a first rotary member 506 and a second rotary member 507, and a first torsion spring 508 and a second torsion spring 509 sleeved on the first rotary member 506 and the second rotary member 507 respectively. The first rotary member 506 and the second rotary member 507 are vertically mounted on a side surface of the locker body 502 facing the second fixed portion 5011. The vertical mounting is that axes of the first rotary member 506 and the second rotary member 507 are perpendicular to the side surface of the locker body 502 facing the second fixed portion 5011. Preferably, to improve the supporting performance of the first rotary member 506 and the second rotary member 507 and ensure a locking effect, the first rotary member 506 and the second rotary member 507 are both fixedly connected to the locker body 502. In addition, the first rotary member 506 and the second rotary member 507 are vertically configured. Specifically, in a physical space, the second rotary member 507 is located above the first rotary member 506.

With reference to FIG. 9 to FIG. 11, the first rotating member 503 is rotatably connected to the first rotary member 506. A V-shaped lock tongue portion 5031 is formed at a top of the first rotating member 503. The lock tongue portion 5031 is close to an end of the second rotating member 504. A bottom of the first rotating member 503 is bent to form a force-applying portion 5032. The force-applying portion 5032 is far away from an end of the second rotating member 504. The first torsion spring 508 is sleeved on the first rotary member 506. In addition, two ends of the first torsion spring 508 are respectively connected with the first blocking portion 5022 and the first rotating member 503. A torsional deformation of the first torsion spring 508 can implement rotatable reset of the first rotating member 503.

The second rotating member 504 is rotatably connected to the second rotary member 507. A V-shaped locking slot 5042 fitting the lock tongue portion 5031 and a U-shaped second lock slot 5041 are opened in the second rotating member 504. It may be understood that, during actual application, provided that a shape of the lock tongue portion 5031 and a shape of the locking slot 5042 complement with each other, the shape of the lock tongue portion 5031 and the shape of the locking slot 5042 are not limited to being V-shaped. The second torsion spring 509 may be sleeved on the second rotary member 507. In addition, two ends of the second torsion spring 509 are respectively connected with the second blocking portion 5023 and the second rotating member 504. A torsional deformation of the second torsion spring 509 can implement rotatable reset of the second rotating member 504. The first torsion spring 508 and the second torsion spring 509 in this embodiment may be equivalently replaced with clockwork springs or other elastic components that have a rotary reset function.

A closing process and an opening process of the overhaul window 300 are described below with reference to the accompanying drawings:

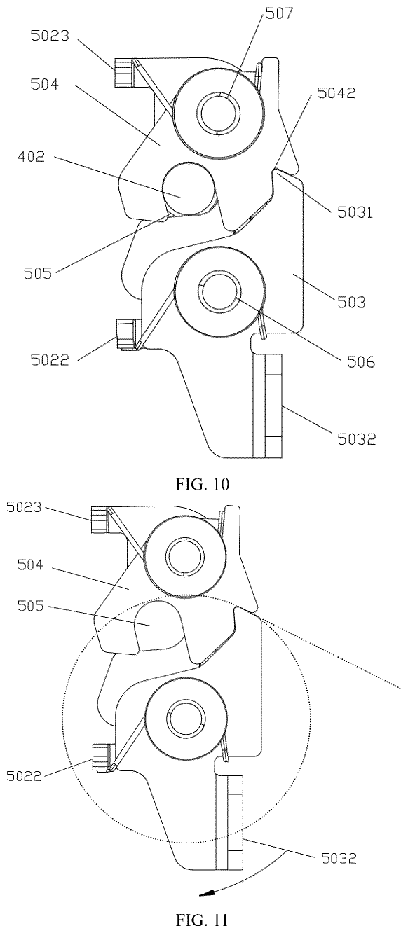

With reference to FIG. 9 and FIG. 10, in the closing process of the overhaul window 300, the second locker unit 500 is close to the first locker unit 400. The locker pin 402 abuts against a slot edge of the second lock slot 5041 and counterclockwise pushes the second rotating member 504 to rotate counterclockwise until the lock tongue portion 5031 of the first rotating member 503 is locked in the locking slot 5042. In this case, the locker pin 402 is locked in a locking space 505 formed through overlapping and surrounding of the first lock slot 5021 and the second lock slot 5041. In this case, the overhaul window 300 is locked tightly. It is defined that in this case the second locker unit 500 is in a first state, that is, the second locker unit 500 is in a locked state.

With reference to FIG. 9 to FIG. 11, when the overhaul window 300 needs to be opened, an external force is applied to the force-applying portion 5032 of the first rotating member 503 to enable the first rotating member 503 to rotate clockwise, and the lock tongue portion 5031 is separated from the locking slot 5042. Under the action of the second torsion spring 509, the second rotating member 504 is reset and rotates, the locking space 505 is opened, and the locker pin 402 is pushed away from the locking space 505. In this case, the overhaul window 300 is unlocked, and the overhaul window 300 can be completely opened manually. It is defined that in this case the second locker unit 500 is in a second state, that is, the second locker unit 500 is in an unlocked state. In addition, the second blocking portion 5023 may limit a rotation angle of the second rotating member 504 after being unlocked. In a case that the second rotating member 504 is limited, the first rotating member 503 is also limited.

In a further embodiment, a slot edge of the first lock slot 5021 close to the first rotating member 503 obliquely extends from a slot opening of the first lock slot 5021 toward the second rotating member 504, to form a preset angle a between the slot edge of the first lock slot 5021 close to the first rotating member 503 and a movement plane direction of the second locker unit 500. As shown in FIG. 9, the preset angle a is formed between a bottom of a slot edge of the first lock slot 5021 and a horizontal direction of the second locker unit 500. When the locker pin 402 is locked, the bottom of the slot edge of the first lock slot 5021 applies an obliquely upward force to the locker pin 402, to avoid a problem of a poor tight locking effect because a slot width of the first lock slot 5021 or the second lock slot 5041 is greater than a diameter of the locker pin 402, thereby avoiding loosening.

In a further embodiment, a vertical direction of an extension direction of a side edge of the lock tongue portion 5031 away from the first rotary member 506 points to a rotation center of the first rotating member 503. That is, the extension direction of the side edge of the lock tongue portion 5031 away from the first rotary member 506 is consistent with a tangent direction of a circle with an axis of the first rotary member 506 as a rotation axis and a distance between the side edge and the first rotary member 506 as a radius at the position. Through this configuration, when the second locker unit 500 is unlocked and the first rotating member 503 rotates in an opposite direction (clockwise rotation), apart from an elastic resistance of the first torsion spring 508, the lock tongue portion 5031 only needs to overcome a frictional resistance applied by the second rotating member 504 but does not need to overcome a rotational resistance of the second rotating member 504 to be separated from the locking slot 5042, thereby reducing an unlocking resistance.

In this embodiment, a first avoidance slot 5013 used for avoiding the locker pin 402 is transversely opened on a side edge of the mounting portion 5012 of the second locker support 501 opposite to the first locker support 401. Through this arrangement, a size of the second locker unit 500 can be reduced, and an occupying space of the second locker unit 500 is reduced. A second avoidance slot 5014 used for avoiding the force-applying portion 5032 is opened at a position of the second fixed portion 5011 close to a bottom. The structural design of the first locker unit 400 and the second locker unit 500 further facilitates the arrangement of the locker units. The locker units are the first locker unit 400 and the second locker unit 500. This ensures an aesthetic effect and avoids the exposure of the locker units to keep the locker units from collision and damage, thereby protecting the locker units. Specifically, a first through hole 304 is provided in a side surface of the overhaul window 300. The first through hole 304 is opposite to the force-applying portion 5032 of the first rotating member 503. When the overhaul window 300 needs to be opened, the second locker unit 500 can be opened by applying a force to the force-applying portion 5032 to enable the first rotating member 503 to rotate clockwise.

### Embodiment 2

It is found out after actual use that to adapt to height differences between different working positions, when an existing height adjustment assembly is used to adjust a height of a conveying device of a photovoltaic robot, because the existing height adjustment assembly has a large design redundancy and a large number of parts, it is complex to install and adjust the overall robot, and on-site implementation requires a heavy workload and a long period, which affects working efficiency.

To resolve the foregoing problem, this embodiment provides a photovoltaic robot. For a structure of the photovoltaic robot, refer to the technical solution in Embodiment 1. Details are not described herein again.

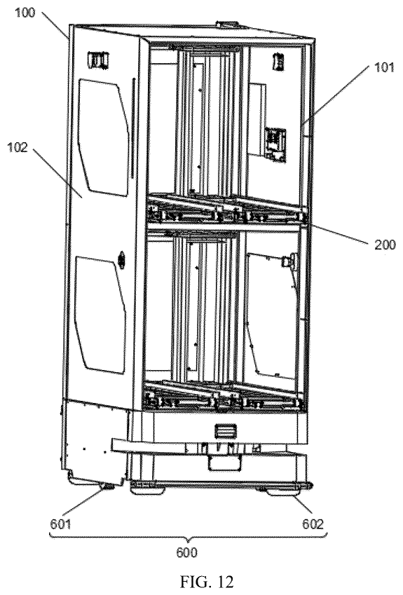

Specifically, with reference to FIG. 12 and FIG. 13, the frame 101 of the photovoltaic robot provided in this embodiment includes at least four vertical supports 1011 and at least two transverse supports 1012. The two transverse supports 1012 are opposite and are horizontally disposed in the middle of two adjacent vertical supports 1011. The two transverse supports 1012 divide the storage device 100 into two vertical layers of storage spaces. It may be understood that, every two transverse supports 1012 may be used as one group. When a plurality of groups of transverse supports 1012 are configured, the storage device 100 is divided into a plurality of layers of storage spaces. Certainly, the transverse support 1012 is disposed between every two adjacent vertical supports 1011, thereby improving the stability of the frame 101.

Preferably, to reduce an impact on a flower basket between two adjacent layers, the partition 103 is further disposed in the frame 101, the partition 103 is disposed on the transverse support 1012, and the subsequent mounting of a fixed plate 901 is not affected.

Further, one or more vertical supports 1011 may further be configured between the two adjacent vertical supports 1011, or, one or more diagonal web members may be further disposed between the two adjacent vertical supports 1011, so that a load can be better carried.

It needs to be noted that, a length of the vertical support 1011 may be designed according to a height of the storage device 100, or, a plurality of vertical rods are sequentially connected according to a height of the storage device 100, that is, the plurality of vertical rods are spliced to obtain the vertical support 1011.

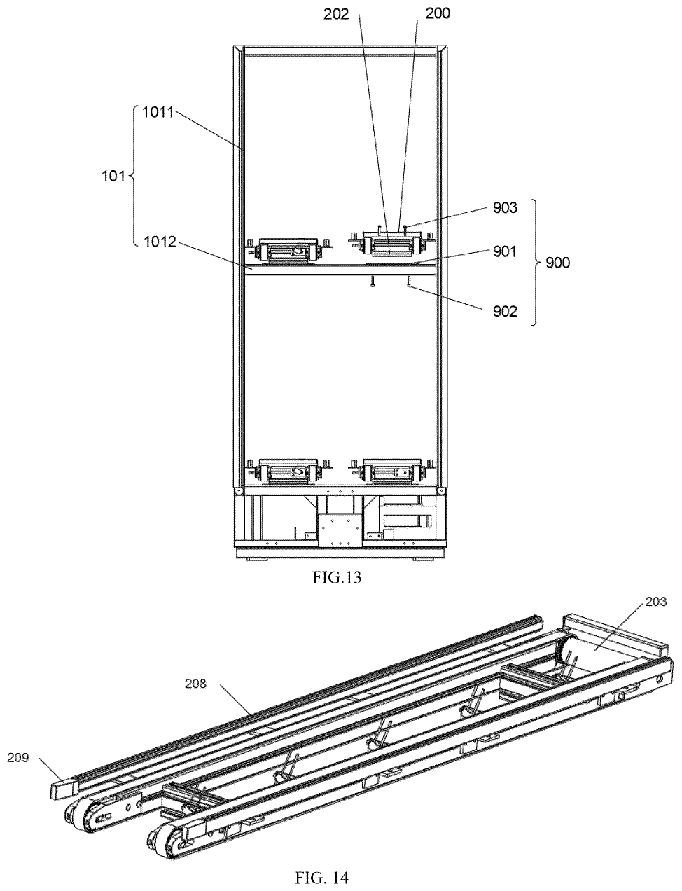

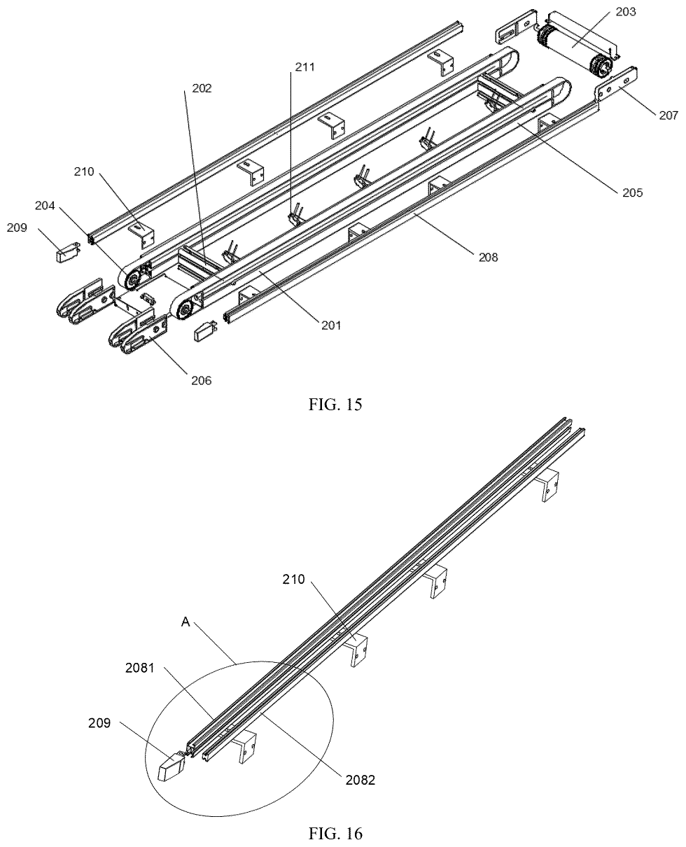

With reference to FIG. 14 and FIG. 15, the conveying device 200 includes a main frame and a conveyance assembly mounted on the main frame. The main frame includes a side support unit 201 and a middle support unit 202. The conveyance assembly includes an electric roller 203, a synchronous pulley 204, a synchronous belt 205, a first fixed base 206, a second fixed base 207, a limiting guide assembly, and a photoelectric detection member 211.

Two side support units 201 are connected by two longitudinally arranged middle support unit 202 to form the main frame of the conveying device 200. The two side support units 201 are disposed opposite, the middle support unit 202 is disposed between the two side support units 201, and two ends of the middle support unit 202 are respectively fixedly connected to the two side support units 201. In addition, a mounting through hole is opened on the middle support unit 202. A limiting strip is fixed at a rear end of the side support unit 201. The first fixed base 206 and the second fixed base 207 are respectively fixed on the two longitudinal ends of the side support unit 201. Two ends of the electric roller 203 are fixed on the middle portions of the two second fixed bases 207 respectively. Peripheral teeth with matching tooth shapes of the synchronous belt 205 are respectively disposed on circumferential surfaces of the two ends of the electric roller 203. The electric roller 203 forms a transmission-connection to the synchronous pulley 204 by the synchronous belt 205. The synchronous pulley 204 is fixed on the first fixed base 206, a penetrating waist-shaped hole is opened in a side surface of the first fixed base 206, the synchronous pulley 204 may move forward along the waist-shaped hole, to tightly tension the synchronous belt 205. An upper surface of the synchronous belt 205 is in direct contact with a to be conveyed flower basket. The electric roller 203 rotates to drive the synchronous belt 205 to move. The flower basket moves together under the action of a static friction of the synchronous belt 205. It can be seen that the electric roller 203 is used for driving. Transmission parts such as a transmission shaft, a transmission belt or a transmission chain, a transmission wheel, and the like do not need to be configured. A small number of parts are required, the structure is simple, the costs are low, and the assembly is time saving and labor saving.

The limiting guide assembly includes a rib 208, a guide strip 209, and a guide strip support member 210, the rib 208 is fixed on two sides of the main frame by the guide strip support member 210, and the guide strip 209 is fixed on an end portion of the rib 208. The rib 208 and the guide strip 209 have a guide effect, to keep a flower basket from deviating. With reference to FIG. 16 and FIG. 17, the rib 208 includes a rib support 2081 and a rib strip 2082. The rib support 2081 is a profile, and the rib support 2081 has a T-shaped slot. The T-shaped slot is used for mounting the rib strip 2082. The rib strip 2082 may be an elastic component, for example, a silicone strip, to produce a particular cushioning action for a flower basket. In addition, the guide strip support member 210 may be an L-shaped angle connecting member. An assembly hole is opened in the L-shaped angle connecting member according to an actual mounting requirement. The limiting guide assembly uses a detachable structure, to facilitate disassembly and assembly and replacement.

A plurality of photoelectric detection members 211 are fixed at a middle position of the main frame. Intervals between the photoelectric detection members 211 are the same as those between flower baskets, to detect whether a flower basket exists above every photoelectric detection member 211. The photoelectric detection member 211 mainly includes a photosensor that converts an optical signal into an electrical signal through a photoelectric effect.

To adjust a height of the conveying device 200 of the photovoltaic robot, a height adjustment assembly 900 is configured in the photovoltaic robot provided in this embodiment. The height adjustment assembly 900 includes the fixed plate 901, at least one first bolt 902, and at least one second bolt 903. The mounting through hole is opened in the fixed plate 901, and in addition, the fixed plate 901 is disposed on an upper surface of the transverse support 1012. During installation or adjustment of the conveying device 200, the first bolt 902 extends through the fixed plate 901 from bottom to top, and abuts against a bottom surface of the middle support unit 202. The first bolt 902 is threadedly connected to the fixed plate 901. A height of the middle support unit 202 is adjusted by adjusting a distance by which the first bolt 902 moves upward, to implement the adjustment of a ground clearance of the conveying device 200. The second bolt 903 extends through the middle support unit 202 from top to bottom, and is threadedly connected to the fixed plate 901. The middle support unit 202 adjusted in place is fixed by the second bolt 903. When the height of the middle support unit 202 needs to be adjusted again, it is only necessary to loosen the second bolt 903 and then adjust the first bolt 902.

Alternatively, the second bolt 903 extends through the middle support unit 202 from top to bottom, and abuts against the top surface of the fixed plate 901, and the second bolt 903 is threadedly connected to the middle support unit 202. The height of the middle support unit 202 is adjusted by rotating the second bolt 903. The first bolt 902 extends through the fixed plate 901 from bottom to top, and is threadedly connected to the middle support unit 202. The middle support unit 202 adjusted in place is fixed by the first bolt 902. When the height of the middle support unit 202 needs to be adjusted again, it is only necessary to loosen the first bolt 902 and then adjust the second bolt 903.

It is obvious that the first bolt 902 and the second bolt 903 are threadedly connected to the fixed plate 901 or the middle support unit 202, and are used for adjusting a distance between and fixing the middle support unit 202 and the fixed plate 901.

Through the combined use of the foregoing two groups of bolts, the height adjustment can be implemented, and the conveying device 200 can be fastened.

As can be seen from the foregoing, the conveying device 200 of the photovoltaic robot only requires two groups of bolts to adjust the ground clearance of the conveying device 200.

In this embodiment, through the two groups of bolts, the ground clearance of the conveying device 200 can be adjusted, and the conveying device 200 can be fastened. The structure is simple, a small number of parts are used, and the installation and adjustment are simple, which helps to improve working efficiency.

### Embodiment 3

It is found out through actual use that an existing integrated AGV/AMR robot requires a dedicated robot chassis (or referred to as a movement mechanism). Components such as a frame, a conveying device, a control module, and the like are integrated above this chassis. The frame is usually an assembled structure. The design, manufacturing, and assembly are complex, and the costs are high. In the photovoltaic market with fierce competition, these become bottlenecks in improving the market competitiveness and profitability for photovoltaic enterprises.

To resolve the foregoing problem, the present invention provides a photovoltaic robot. For a structure of the photovoltaic robot, refer to the technical solution in Embodiment 1 or Embodiment 2. Details are not described herein again.

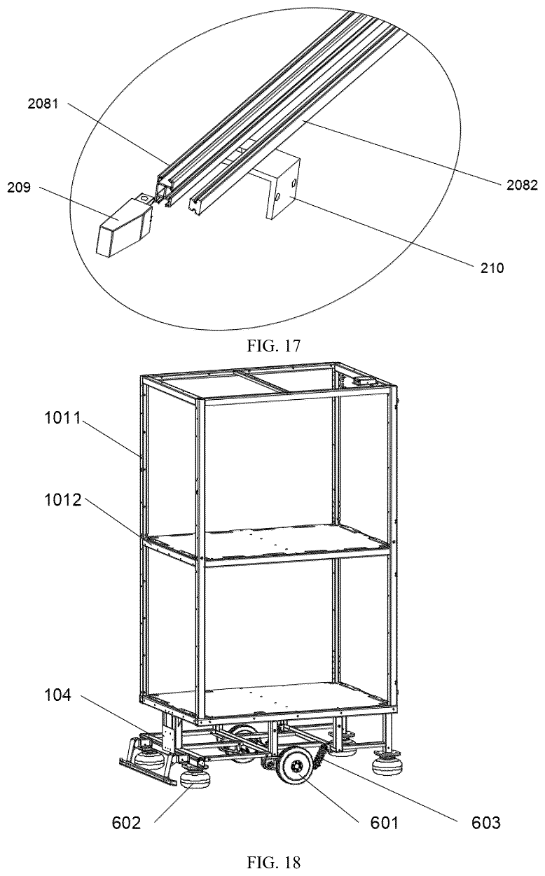

Specifically, as shown in FIG. 18, a photovoltaic robot provided in this embodiment further includes a connecting frame 104 disposed at a bottom of the body frame. The connecting frame 104 is used for mounting the walking mechanism 600. The walking mechanism 600 enables the photovoltaic robot to walk in any direction.

A specific structural form of the body frame is a structural form of the body frame in Embodiment 2. Therefore, details are not described herein again.

The connecting frame 104 includes at least one connecting support and at least one single-layer frame. One end of the connecting support is connected to the bottom of the body frame, and the other end of the connecting support is connected to an upper surface of the single-layer frame. The single-layer frame includes at least two main beams parallel to each other, a node is formed between every two main beams, and the connecting support is disposed at the node. To improve the stability and load-carrying performance of the connecting frame 104, the connecting support is disposed at the node of the single-layer frame.

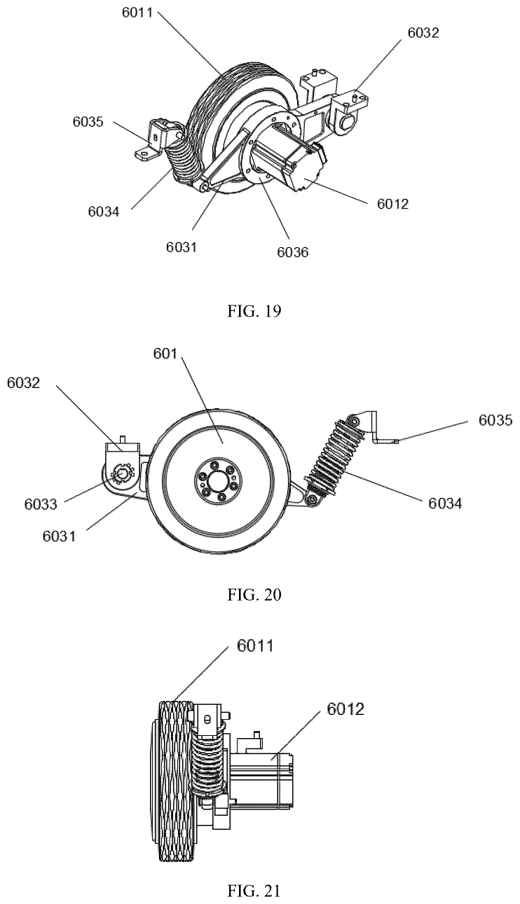

With reference to FIG. 19 to FIG. 21, the walking mechanism 600 includes a plurality of drive wheels 601 and a plurality of driven wheels 602. The plurality of drive wheels 601 are disposed in the middle of the connecting frame 104, and the plurality of driven wheels 602 are disposed at a bottom of the connecting frame 104. The drive wheel 601 has a power source used for driving the storage device 100 to move. The driven wheel 602 is used for supporting the storage device 100.

Specifically, the drive wheel 601 includes a driving wheel 6011 and a drive motor 6012. An output end of the drive motor 6012 is connected to the driving wheel 6011. The drive motor 6012 is used as a power input of the driving wheel 6011. That is, the driving wheel 6011 may be a reduction-drive wheel connected with a motor.

The plurality of driven wheels 602 are directly connected to a bottom of the storage device 100, that is, the connecting frame 104 by a bolt, and a dedicated fixing bottom plate does not need to be disposed.

Further, to enable the drive wheel 601 to keep a tight contact state with the ground all the time and avoid suspension and skidding of the drive wheel 601 over bumpy ground and steps, the walking mechanism 600 further includes a suspension mechanism 603 disposed in the middle of the connecting frame 104. The drive wheel 601 is mounted at the suspension mechanism 603.

The suspension mechanism 603 includes a swing member 6031, a third fixed base 6032, a connecting member 6033, an elastic member 6034, and a support base 6035. Through holes are designed at two ends of the swing member 6031. A mounting flange 6036 and a mounting hole opened in the middle are designed in a side surface in the middle. The third fixed base 6032 is fixed at the bottom of the connecting frame 104. The through hole at one end of the swing member 6031 is connected to the third fixed base 6032 through the connecting member 6033, and the through hole at the other end is hinged to a bottom of the elastic member 6034. A head portion of the elastic member 6034 is hinged to the connecting frame 104 by the support base 6035. The driving wheel 6011 is fixed on the mounting flange 6036 on the side surface of the swing member 6031 by a bolt. An output shaft of the drive motor 6012 extends through the mounting flange 6036 of the swing member 6031 to be rotatably connected to a reduction box of the driving wheel 6011. The driving wheel 6011 is in contact with the ground. Specifically, the swing member 6031 may be a rocker arm lever. The connecting member 6033 may be a pin shaft. The elastic member 6034 may be a spring buffer, a rubber buffer, a hydraulic buffer, or the like. The spring buffer has a relatively simple structure, the use is reliable, and repair is convenient. When the spring buffer is impacted, energy of the spring buffer is mainly converted into compression energy of a spring, and therefore a large bouncing force is produced. The rubber buffer has a simple structure. However, the rubber buffer can absorb a small amount of energy, and mainly implement blocking. The hydraulic buffer absorbs a large amount of impact energy. The stroke of the hydraulic buffer may be short, and therefore the hydraulic buffer has a small size. A person skilled in the art may select and adjust the elastic member 6034 as required.

Through the foregoing configuration, a force arm of the elastic member 6034 is greater than a pressing force arm of the drive wheel 601. Through the swing member 6031, the elastic member 6034 and the third fixed base 6032 form a swing configuration of rotating in an axial direction of the connecting member 6033. Beneficial effects brought by the configuration belt are as follows: The overall structure is compact and simple and has a small weight. The elastic member 6034 only requires a small force to apply a large ground pressing force on the drive wheel 601, to enable the drive wheel 601 to keep a tight contact state with the ground all the time, thereby avoiding suspension and skidding over bumpy ground and steps. In addition, the drive wheel 601 in this embodiment does not carry the weights of the frame and other structures. This part of weight is carried by the driven wheel 602. In this way, the service life of the drive wheel 601 can be improved. In addition, two drive motors 6012 may be electrically connected to a control unit, and are used for walking control of the photovoltaic robot.

A dedicated shock absorption mechanism needs to be configured for an existing integrated AGV/AMR robot to avoid skidding of a drive wheel. Every shock absorption mechanism has a plurality of hinged supports. The design is complex, the costs are high, and the consistency is low. Compared with this, for the walking mechanism 600 provided in the present invention, while the walking performance and adjustability of the photovoltaic robot are improved, the structure is simple, the production costs are low, and the consistency is high.

### Embodiment 4

This embodiment provides a photovoltaic robot. For a structure of the photovoltaic robot, refer to the technical solution in any one of Embodiment 1 to Embodiment 3. Details are not described herein again.

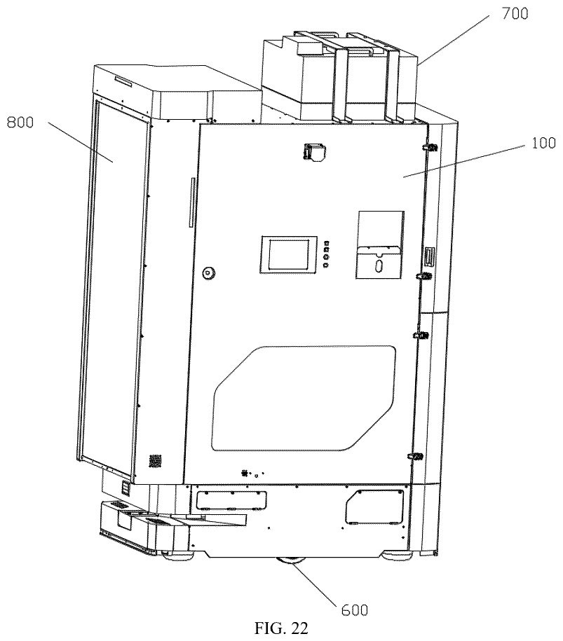

Specifically, with reference to FIG. 22, the photovoltaic robot provided in this embodiment further includes an air purification device 700 disposed at a top of the storage device 100. The air purification device 700 purifies air and introduces the purified air into the storage device 100 to form a high pressure in the storage device 100, to keep external floating dust from entering the storage device 100, thereby keeping a silicon wafer on a flower basket in the storage device 100 clean.

### Embodiment 5

This embodiment provides a photovoltaic robot. For a structure of the photovoltaic robot, refer to the technical solution in any one of Embodiment 1 to Embodiment 4. Details are not described herein again.

Specifically, with reference to FIG. 22, the photovoltaic robot provided in this embodiment further includes a roller shutter device 800 disposed on a side of the storage device 100 away from the overhaul window 300. The roller shutter device 800 is formed by connecting multi-joint movable door slats in series or is a flexible curtain. In a fixed slide, a vertical door is rotated with a reel above the door as the center. An electric device is used to control the vertical movement and rolling of the door, to separate the outside from the interior of the storage device 100.

In the description of the embodiments of the present invention, it further needs to be noted that unless otherwise expressly specified and defined, the terms “disposed” and “connected” should be understood in a broad sense, for example, fixedly connected, detachably connected, or integrally connected; or mechanically connected, or electrically connected; or connected directly or through an intermediate, or two elements communicated internally. A person of ordinary skill in the art may understand specific meanings of the foregoing terms in the present invention to specific cases.

Obviously, the foregoing embodiments are merely examples for clear description, rather than a limitation to implementations. For a person of ordinary skill in the art, other changes or variations in different forms may also be made based on the foregoing description. All implementations cannot and do not need to be exhaustively listed herein. Obvious changes or variations that are derived there from still fall within the protection scope of the invention of the present invention.

What is claimed is:

1. A photovoltaic robot, comprising:
a robot body, comprising a storage device (100) and a walking mechanism (600) disposed at a bottom of the storage device (100), wherein openings are provided on two sides of the storage device (100), and an interior space of the storage device (100) is defined as a storage space;
a conveying device (200), horizontally disposed in the storage space of the storage device (100), wherein two ends of the conveying device (200) extend out of the storage space from the openings on the two sides of the storage device (100); and
an overhaul window (300), hinged to the storage device (100) at an opening on a side of the storage device (100), wherein the overhaul window (300) is recessed from inside to outside to form an avoidance space (302).

2. The photovoltaic robot according to claim 1, further comprising a first locker unit (400) disposed at an opening of the storage device (100) and a second locker unit (500) disposed at a side edge of the overhaul window (300), wherein the first locker unit (400) and the second locker unit (500) fit to each other and are used for locking the overhaul window (300) after being closed.

3. The photovoltaic robot according to claim 2, wherein the first locker unit (400) comprises a first locker support (401) fixed at an opening of the storage device (100) and a locker pin (402) disposed on the first locker support (401);
the second locker unit (500) comprises a second locker support (501) fixedly mounted at the side edge of the overhaul window (300), a locker body (502) fixed on the second locker support (501), and a first rotating member (503) and a second rotating member (504) that are rotatably connected to the locker body (502) and are rotatably resettable; a first lock slot (5021) is transversely opened on a side of the locker body (502) close to the first locker unit (400); the first rotating member (503) comprises a lock tongue portion (5031) close to an end of the second rotating member (504) and a force-applying portion (5032) away from the end of the second rotating member (504); a second lock slot (5041) and a locking slot (5042) are separately opened on a side edge of the second rotating member (504); and the second locker unit (500) is configured to comprise a first state and a second state;
when the second locker unit (500) is close to the first locker unit (400), the locker pin (402) abuts against a slot edge of the second lock slot (5041) and pushes the second rotating member (504) to rotate until the lock tongue portion (5031) of the first rotating member (503) is locked in the locking slot (5042), in this case, the locker pin (402) is locked in a locking space (505) formed through overlapping and surrounding of the first lock slot (5021) and the second lock slot (5041), and the second locker unit (500) is in the first state; and
when an external force is applied to the force-applying portion (5032) of the first rotating member (503) to enable the lock tongue portion (5031) to be separated from the locking slot (5042), the second rotating member (504) is reset and rotates, the locking space (505) is opened, the locker pin (402) is pushed away from the locking space (505), and the second locker unit (500) is in the second state.

4. The photovoltaic robot according to claim 3, wherein the second locker unit (500) further comprises a first rotary member (506) and a second rotary member (507) that are vertically mounted on the locker body (502), a first torsion spring (508) sleeved on the first rotary member (506), and a second torsion spring (509) sleeved on the second rotary member (507); two end portions of the first torsion spring (508) are respectively connected with the locker body (502) and the first rotating member (503);
and two end portions of the second torsion spring (509) are respectively connected with the locker body (502) and the second rotating member (504).

5. The photovoltaic robot according to claim 4, wherein a side of the locker body (502) is bent to form a first blocking portion (5022) used for being connected with the first torsion spring (508) and a second blocking portion (5023) used for being connected with the second torsion spring (509), and the second blocking portion (5023) is further configured to limit the second rotating member (504) after being rotated and reset.

6. The photovoltaic robot according to claim 3, wherein a slot edge of the first lock slot (5021) close to the first rotating member (503) obliquely extends from a slot opening of the first lock slot (5021) toward the second rotating member (504), to form a preset angle a between the slot edge of the first lock slot (5021) close to the first rotating member (503) and a movement plane direction of the second locker unit (500).

7. The photovoltaic robot according to claim 4, wherein a vertical direction of an extension direction of a side edge of the lock tongue portion (5031) away from the first rotary member (506) points to a rotation center of the first rotating member (503).

8. The photovoltaic robot according to claim 3, wherein the first locker support (401) comprises a first fixed portion (4011) and a first support portion (4012), and the first fixed portion (4011) is fixedly connected to the storage device (100); and the locker pin (402) is detachably mounted on the first support portion (4012);
the second locker support (501) comprises a second fixed portion (5011) fixedly connected to an inner wall of the overhaul window (300) and a mounting portion (5012) fixedly connected to the second fixed portion (5011); the locker body (502) is fixedly mounted on a side of the mounting portion (5012) close to the second fixed portion (5011); a first avoidance slot (5013) used for avoiding the locker pin (402) is transversely opened on a side edge of the mounting portion (5012) opposite to the first locker support (401); and a second avoidance slot (5014) used for avoiding the force-applying portion (5032) is opened in the second fixed portion (5011); and
a through hole (304) is opened on a side edge of the overhaul window (300) for performing an operation on the force-applying portion (5032).

9. The photovoltaic robot according to claim 1, further comprising an air purification device (700) disposed at a top of the storage device (100).

10. The photovoltaic robot according to claim 1, further comprising a roller shutter device (800) disposed at an opening on a side of the storage device (100) away from the overhaul window (300).

11. The photovoltaic robot according to claim 1, wherein the conveying device (200) comprises a main frame and a conveyance assembly mounted on the main frame, the main frame comprises a middle support unit (202) and two side support units (201) that are disposed opposite to each other, and the middle support unit (202) is disposed between the two side support units (201); and
the photovoltaic robot further comprises a height adjustment assembly (900), the height adjustment assembly (900) comprises a fixed plate (901), a first bolt (902), and a second bolt (903), the fixed plate (901) is disposed on the storage device (100), and the first bolt (902) and the second bolt (903) are threadedly connected to the fixed plate (901) or the middle support unit (202), and are used for adjusting and fixing a distance between the middle support unit (202) and the fixed plate (901).

12. The photovoltaic robot according to claim 11, wherein the conveyance assembly comprises an electric roller (203) disposed on one end of the side support unit (201), a synchronous pulley (204) disposed on the other end of the side support unit (201), and a synchronous belt (205) transmission-connected to the electric roller (203) and the synchronous pulley (204); and peripheral teeth that fit the synchronous belt (205) by a transmission way are disposed on a peripheral surface of the electric roller (203).

13. The photovoltaic robot according to claim 11, wherein the first bolt (902) extends through the fixed plate (901) from bottom to top and abuts against a bottom surface of the middle support unit (202), and the first bolt (902) is threadedly connected to the fixed plate (901); and the second bolt (903) extends through the middle support unit (202) from top to bottom and is threadedly connected to the fixed plate (901).

14. The photovoltaic robot according to claim 11, wherein the first bolt (902) extends through the fixed plate (901) from bottom to top and is threadedly connected to the middle support unit (202); and the second bolt (903) extends through the middle support unit (202) from top to bottom and abuts against a top surface of the fixed plate (901), and the second bolt (903) is threadedly connected to the middle support unit (202).

15. The photovoltaic robot according to claim 11, wherein the conveyance assembly further comprises a limiting guide assembly, the limiting guide assembly comprises a rib (208), a guide strip (209), and a guide strip support member (210), the rib (208) is fixed on two sides of the main frame by the guide strip support member (210), and the guide strip (209) is fixed on an end portion of the rib (208).

16. The photovoltaic robot according to claim 15, wherein the rib (208) comprises a rib support (2081) fixed on the guide strip support member (210) and a rib strip (2082) that is disposed on an inner side of the rib support (2081) and is detachably connected to the rib support (2081).

17. The photovoltaic robot according to claim 1, wherein the storage device (100) comprises a body frame and a connecting frame (104) disposed at a bottom of the body frame; the connecting frame (104) comprises at least one connecting support and at least one single-layer frame, one end of the connecting support is connected to the bottom of the body frame, and an other end of the connecting support is connected to an upper surface of the single-layer frame; the walking mechanism (600) comprises a plurality of drive wheels (601) disposed in a middle of the connecting frame (104) and a plurality of driven wheels (602) disposed at a bottom of the connecting frame (104); the drive wheels (601) has a power source and are used for driving the storage device (100) to move; and the driven wheels (602) are used for supporting the storage device (100).

18. The photovoltaic robot according to claim 17, wherein the single-layer frame comprises at least two main beams parallel to each other, a node is formed between every two main beams, and the connecting support is disposed at the node.

19. The photovoltaic robot according to claim 17, wherein the walking mechanism (600) further comprises a suspension mechanism (603) disposed in the middle of the connecting frame (104); the drive wheels (601) are mounted on the suspension mechanism (603); the suspension mechanism (603) comprises a swing member (6031) and an elastic member (6034); two ends of the swing member (6031) are rotatably connected to the connecting frame (104) and the elastic member (6034) respectively; and an end portion of the elastic member (6034) away from the swing member (6031) is rotatably connected to the connecting frame (104).

20. The photovoltaic robot according to claim 19, wherein the suspension mechanism (603) further comprises a third fixed base (6032) and a support base (6035) fixedly connected to the bottom of the connecting frame (104), and the swing member (6031) is hinged to the third fixed base (6032); and the elastic member (6034) is hinged to the support base (6035).
